(19) United States
(12) Patent Application Publication
(10) Pub. No.: US 2003/0141591 A1
(43) Pub. Date: Jul. 31, 2003

(54) Under bump structure and process for producing the same

(76) Inventors: Chih-Hsiang Hsu, Kaoshiung (TW); Shih-Kuang Chen, Kaoshiung (TW); Chia-Hung Cheng, Kaoshiung (TW); Min-Lung Huang, Kaoshiung (TW)

Correspondence Address: SEYFARTH SHAW, Suite 4200, 55 East Monroe Street, Chicago, IL, 60603-5803, US

(21) Appl. No.: 10/351,667

(22) Filed: Jan. 27, 2003

(30) Foreign Application Priority Data
Jan. 30, 2002 (TW) 091101571

(51) Int. Cl. H01L 29/40

(52) U.S. Cl. 257/737

(57) ABSTRACT

The present invention relates to an under bump structure comprising a wafer surface including a plurality of pads; a plurality of passivation layers covering the wafer surface around the pads; a dielectric layer covering the wafer surface and the passivation layers, each of the passivation layer and the dielectric layer having a first opening at a position corresponding to that of each pad for exposing the pad; and an under bump metallurgy layer covering the dielectric layer, the pads and the passivation layers to connect the pads.

### BACKGROUND OF THE INVENTION

1. Field of the invention

The present invention relates to a wafer structure, particularly to an under bump structure and a process for producing the same.

2. Description of the Related Art

For the modern life, electronic products tend to have multi-functions. Hence, electrical connection between electronic elements becomes more and more complicated. Besides connecting with fabricated dies, wafer production nowadays engages in connecting units in a wafer.

Referring to FIG. 1, a conventional under bump structure 1 comprises a wafer surface 11 including a plurality of pads 111. A passivation layer 12 covers the wafer surface 11 around each pad 111. The passivation layer 12 is often made of a dielectric material for protecting and isolating the wafer surface 11, and comprises a first opening 121 having a plurality of slants 122 in the positions corresponding to those of the pads 111 for exposing the pads 111. A first obtuse angle θ₁ is formed between each slant 122 and each pad 111, and a fist right angle θ₂ is formed between the passivation layer 12 and the wafer surface 11. In order to form a bump (not shown) on the under bump structure 1 to further set a wire (not shown), an under bump metallurgy layer 14 is needed to cover the pad 111 and the passivation layer 12.

The single under bump metallurgy layer 14 is used to cover the two pads 111, passivation layer 12 and wafer surface 11 in this field for the purpose of connecting two pads 111. Sputtering to form the under bump metallurgy layer 14 is often used. Although sputtering forms a good structure at the first obtuse angle θ₁, the plating solution cannot be distributed evenly at the first right angle θ₂, and thus the under bump metallurgy layer 14 breaks at the position corresponding to the connection between the passivation layer 12 and the wafer surface 11 (as shown in FIG. 1) and fails to connect the two pads 111. To solve the problem, electroplating is used in this field; however, it raises the cost and difficulty of operation.

Accordingly, an innovative and advanced under bump structure and a process for producing the same is developed so as to solve the breakage problem of the under bump metallurgy layer.

### SUMMARY OF THE INVENTION

One objective of the present invention is to provide an under bump structure comprising a wafer surface including a plurality of pads; a plurality of passivation layers covering the wafer surface around the pads; a dielectric layer covering the wafer surface and the passivation layers, each of the passivation layer and dielectric layer having a first opening at the position corresponding to that of each pad for exposing the pad; and an under bump metallurgy layer covering the dielectric layer, the pads and the passivation layers to connect the pads. The present invention can solve the breakage problem occurring in the under bump metallurgy layer between the pads by using metal sputtering of the prior art.

Another objective of the present invention is to provide a process for producing a connectable under bump structure, which comprises the steps of:

(a) providing a wafer, and providing a plurality of pads on a wafer surface of the wafer and a plurality of passivation layers covering the wafer surface around the pads, wherein each passivation layer has a first opening at the position corresponding to each pad for exposing the pad;

(b) forming a dielectric layer on the wafer surface between the pads and the two adjacent passivation layers in step (a) and on the passivation layers;

(c) etching the dielectric layer formed in step (b) at positions corresponding to those of the first openings for exposing the pads; and

(d) forming an under bump metallurgy layer on the pads, the passivation layers and the dielectric layer for connecting the pads exposed by the first openings.

### BRIEF DESCRIPTION OF THE DRAWINGS

FIG. 1 shows the partial cross-sectional view of the conventional under bump; and

FIGS. 2a to 2d show the partial cross-sectional view of an under bump according to one preferred embodiment of the invention illustrating the steps of producing the same.

### DETAILED DESCRIPTION OF THE INVENTION

As used herein, the term “under bump structure” comprises a plurality of pads electrically connected to each other and to electric components under the pads in a wafer. Usually, one single wafer can include many under bump structures.

Preferred Embodiment

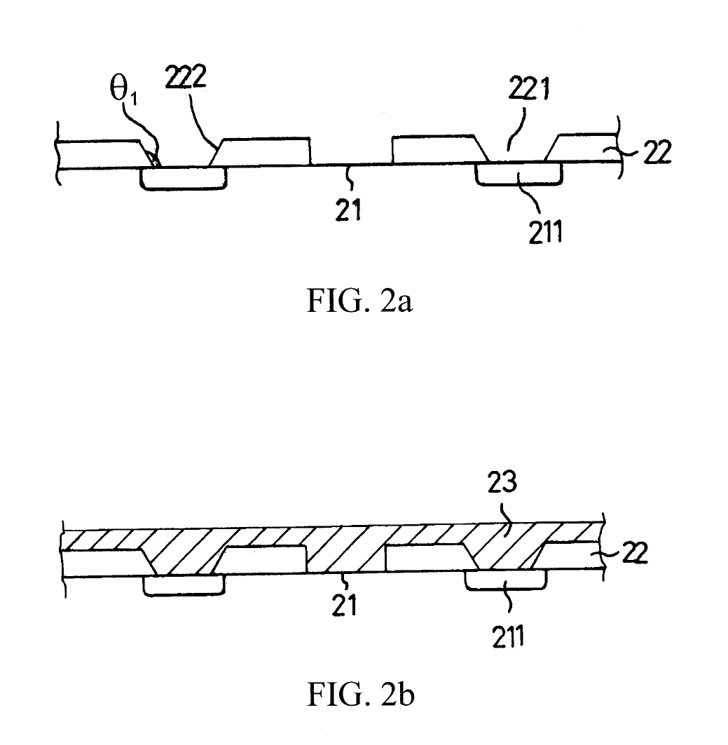

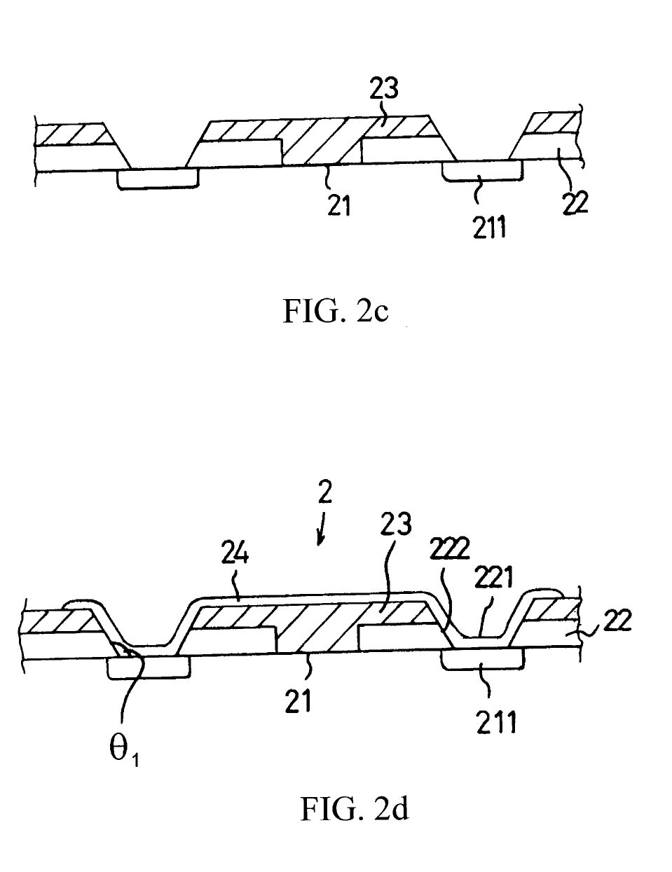

Referring to FIG. 2d, an under bump structure 2 comprises a wafer surface 21 on a wafer, the wafer surface 21 including a plurality of pads 211. To protect and isolate the wafer surface 21, a plurality of passivation layers 22 cover the wafer surface 21 around the pads 211. In order to form an under bump metallurgy layer 24 on the pads 211 and the passivation layers 22, a dielectric layer 23 is formed to cover the wafer surface 21 and the passivation layers 22. Each of the passivation layer 22 and the dielectric layer 23 has a first opening 221 at the position corresponding to each pad 211 for exposing the pads 211. The first opening 221 has a plurality of slants 222 formed by the passivation layer 22 and the dielectric layer 23. A first obtuse angle θ₁ is formed between the slant 222 and the pad 211. In order to electrically connect the pads 211, the dielectric layer 23 structurally connects the pads 211. The single under bump metallurgy layer 24 covers the dielectric layer 23, the pads 211 and the passivation layers 22 to electrically connect the pads 211 exposed through the first opening 221.

Process

A process for producing connectable under bump structure 2 according to the invention is sequentially shown in FIGS. 2a to 2d.

First, a wafer (not shown) is provided. The wafer is usually a semimanufactured product and comprises a plurality of electrically connecting or not connecting under bump structures. The present invention provides a process of producing the under bump structures that connect to each other. In FIG. 2a, the process provides a plurality of pads 211 on a wafer surface 21. The material of the pads 211 preferably comprises aluminum or copper. A plurality of passivation layers 22 cover the wafer surface 21 around the pads 211 to protect and isolate the wafer surface 21 around the pads 211. Each passivation layer 22 comprises a first opening 211 having a plurality of slants 222 in the position corresponding to each pad 211, and the angle between each slant 222 and pad 211 is a first obtuse angle θ₁.

Referring to FIG. 2b, a dielectric layer 23 is formed on the wafer surface 21 between the pads 211 and the two adjacent passivation layers 22 as well as on the passivation layers 22. Preferably, the dielectric layer 23 is formed by membrane coating and deposing to fill the first opening 221 in FIG. 2a and extends to the passivation layer 22 between two adjacent pads such that a plane is formed. The material of the dielectric layer 23 preferably comprises polyimide, and more preferably, comprises bis-benzocyclobutane.

Referring to FIG. 2c, the dielectric layer 23 in FIG. 2b is etched at the positions corresponding to the first openings 221 to expose the pads 211. The positions to be etched are first exposed, and then are etched by developing.

Referring to FIG. 2d, an under bump metallurgy layer 24 is formed on the pads 211, passivation layers 22 and dielectric layer 23 to cover the first openings 221 in FIGS. 2a and 2c. The under bump metallurgy layer 24 is made of conductive material, which is able to electrically connect circuits between and outside the pads 211.

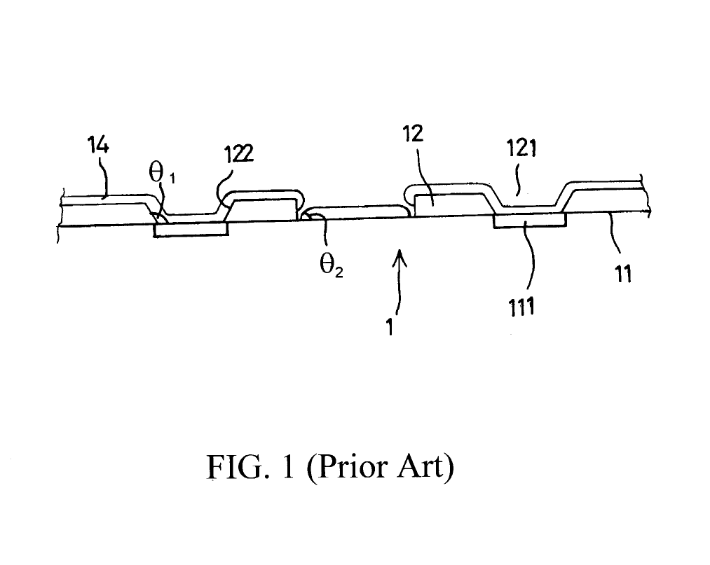

The benefit of the invention is to provide the dielectric layer 23 that provides good support to the under bump metallurgy layer 24. Because all corners of the under bump metallurgy layer 24 are obtuse, the sputtering layer covers the wafer completely to complete the connection between the pads 211 avoiding breakage in the prior art due to the first right angle θ₂ (as shown in FIG. 1) between the passivation layer 12 and the wafer surface 11. Furthermore, the mechanical strength of the under bump metallurgy layer 24 is strengthened, making the under bump structure 2 more stable.

Several under bump structures according to the invention can be set on one wafer to meet the requirements of mass production. Besides, another bump can be set on the under bump metallurgy layer according to the invention to further set a wire. The material of the bump can comprise tin and/or lead. The number and size of the pad, the shape of the opening, the etching and forming ways of the under bump structure according to the invention can be any conventional designs. Forming the under bump metallurgy layer by using metal sputtering to cover the dielectric layer is what is sought to be protected.

While an embodiment of the present invention has been illustrated and described, various modifications and improvements can be made by those skilled in the art. The embodiment of the present invention is therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. An under bump structure comprising:
a wafer surface including a plurality of pads;
a plurality of passivation layers, each passivation layer covering the wafer surface around the pads;
a dielectric layer covering the wafer surface and the passivation layer, each of the passivation layer and the dielectric layer having a first opening at a position corresponding to that of each pad for exposing the pad; and
an under bump metallurgy layer covering the dielectric layer, the pads and the passivation layers to connect the pads.

2. The under bump structure according to claim 1, wherein the first opening has a plurality of slants formed by the passivation layer and the dielectric layer, and the angle between the slant and the pad is a first obtuse angel.

3. The under bump structure according to claim 1, wherein the material of the pads comprises aluminum.

4. The under bump structure according to claim 1, wherein the material of the pads comprises copper.

5. The under bump structure according to claim 1, wherein the material of the dielectric layer comprises polyimide.

6. The under bump structure according to claim 1, wherein the material of the dielectric layer comprises bis-benzocyclobutane.

7. The under bump structure according to claim 1 further comprising a plurality of bumps, wherein each bump is disposed on the under bump metallurgy layer.

8. A wafer comprising the under bump structure according to claim 1.

9. A process for producing a connectable under bump structure, which comprises the steps of:
(a) providing a wafer, and providing a plurality of pads on a wafer surface of the wafer and a plurality of passivation layers covering the wafer surface around the pads, wherein each passivation layer has a first opening at the position corresponding to each pad for exposing the pad;
(b) forming a dielectric layer on the wafer surface between the pads and the two adjacent passivation layers in step (a) and on the passivation layers;
(c) etching the dielectric layer formed in step (b) at positions corresponding to those of the first openings to expose the pads; and
(d) forming an under bump metallurgy layer on the pads, the passivation layers and the dielectric layer for connecting the pads exposed by the first openings.

10. The process according to claim 9, wherein forming the dielectric layer in step (b) is by coating.

11. The process according to claim 9, wherein etching the dielectric layer at the positions corresponding to the first openings in step (c) is by exposing and developing.

12. The process according to claim 9, wherein forming the under bump metallurgy layer in step (d) is by metal sputtering.

13. The process according to claim 9, wherein the first opening has a plurality of slants formed by the passivation layers and the dielectric layer, and the angle between each of the slant and the pad is a first obtuse angel.

14. The process according to claim 9, wherein the material of the dielectric layer comprises polyimide.

15. The process according to claim 9, wherein the material of the dielectric layer comprises bis-benzocyclobutane.
